(19) United States
(12) Patent Application Publication
(10) Pub. No.: US 2026/0133266 A1
(43) Pub. Date: May 14, 2026

(54) SYSTEMS AND METHODS RELATED TO IMAGE PROJECTION AND DISPLAY IN AN MRI BORE

(71) Applicant: PDC FACILITIES, INC., HARTLAND, WI (US)

(72) Inventors: JAMES P. MASLOWSKI, WAUWATOSA, WI (US); MATTHEW K. MURPHY, MUKWONAGO, WI (US); JONATHAN T. CARLSON, UNION GROVE, WI (US)

(21) Appl. No.: 19/118,970

(22) PCT Filed: Oct. 16, 2023
(86) PCT No.: PCT/US2023/077028

§ 371 Date: Apr. 7, 2025

Related U.S. Application Data
(60) Provisional application No. 63/379,506, filed on Oct. 14, 2022.

(51) Int. Cl. G01R 33/28; G01R 33/36; G03B 21/28

(52) U.S. Cl. CPC G01R 33/283; G01R 33/3692; G03B 21/28

(57) ABSTRACT

Systems and methods for transmitting a communication signal (including still and/or video image data) into an RF-shielded MRI room and projecting an image inside an MRI bore based on the data obtained from the signal are disclosed. A signal generating source transfers an electronic (wired (e.g., HDMI) or wireless) communication signal to a transmitter located outside an MRI room, which relays the signal (at a first frequency) through a window glazing disposed in a wall of the MRI room. The relayed communication signal is received by an in-room relay device, which relays the signal (at a second frequency) to a projector located within the MRI bore.

### BACKGROUND

Any type of medical procedure may be anxiety inducing in patients, especially procedures routinely associated with higher risk diagnoses, which may be exacerbated when combined with other anxiety-inducing factors. For example, magnetic resonance imaging (MRI) scans may cause mild to severe cases of anxiety due to feelings of claustrophobia and isolation in conjunction with fears of diagnoses. Anxiety is both uncomfortable for the patient and potentially damaging to the results of the scan if the patient cannot relax. One of the easiest ways to relax a patient is through audio and/or visual entertainment. However, it is difficult to control electromagnetic interference and equipment susceptibility due to high static magnetic fields.

Past attempts to provide entertainment to patients have involved light boxes and/or projected images into the MRI scan room itself. However, these attempts often only displayed static photographic images and may be difficult or impossible for a patient to view while inside the MRI bore during a scan. Applicant has also previously provided solutions to this problem in the form of a ceiling panel capable of displaying slideshows or videos of the patient's choice, as embodied in U.S. Pat. No. 10,226,179 B2. Improved and simplified systems and methods for providing audio and/or visual entertainment to patients in MRI rooms, at a time before, during and/or after an MRI scan, may be desired.

### SUMMARY OF THE INVENTION

Embodiments according to the present invention relate generally to image projection in a radio frequency (RF) room. More specifically, the invention relates to image (e.g., still or video) projection for viewing by patients during an MRI procedure.

According to an aspect of an embodiment of a system according to the present invention, a system for projecting an image within an MRI machine bore includes a projector and a mirror, both of which may be located within the bore. A first transceiver (providing integrated or discrete receiver (preferably wireless) and transmitter (wired or wireless) is in communication with the projector. A second transceiver (providing integrated or discrete receiver (wired or wireless) and transmitter (preferably wireless) functionality) is in communication (preferably wireless communication) with the first transceiver. An audio-visual data source is in wired or wireless communication with the second transceiver. The audio-visual data source produces a first signal including video data, still image (photographic or instructional) data and/or sound data, which is communicated from the audio-visual data source to the second transceiver. The second transceiver produces a second signal (preferably a 60 GHz wireless signal), which may be limited to the data from the first signal, may include data derived from the first signal, and/or further include control data, to be sent to the first transceiver, at least a portion of which is then passed (e.g., through a wired or wireless (e.g., 5 GHz)) to the projector. The projector then projects a still or video image decoded from the second signal onto the mirror which reflects the image onto a toroidally inward facing surface of the MRI machine bore for display.

According to another aspect of an embodiment of a system according to the present invention, the first transceiver is positioned within an MRI (radiation shielded) room and the second transceiver and audio-visual data source are positioned outside the MRI room.

According to still another aspect of an embodiment of a system according to the present invention, a printed circuit board (PCB) receives data from the first transceiver, decodes the data into an output, and transmits the output to the projector through direct electrical connection (e.g., wire).

According to yet another aspect of an embodiment of a system according to the present invention, the system includes an RF-shielded case comprising an aperture through which the image is projected. Both the projector and PCB are preferably located within the RF-shielded case. The RF-shielded case preferably further includes an electromagnetic radiation limiting configuration, such as a waveguide, directional mesh, or random mesh.

According to a further aspect of an embodiment of a system according to the present invention, the PCB receives electrical power from a power source (e.g., battery, mains outlet, jack provided on the MRI machine) and the PCB converts and transfers power from the power source to the projector.

According to a still further aspect of an embodiment of a system according to the present invention, the system the PCB further comprises a radio receiver (preferably 5 GHz), a memory component, and a storage component, wherein the memory component (preferably non-volatile) temporarily stores the data while it is being prepared for output to the projector.

According to an aspect of an embodiment of a method according to the present invention, a method for projecting an image and/or video in an MRI bore includes the step of receiving, at an outside receiver/transmitter located outside an MRI room, still image, audio, and/or video data from an audio-visual source. In a first transmitting step, the data (or representations thereof) and/or control data is transmitted (preferably wirelessly at about 60 GHz) from the outside receiver/transmitter to an inside receiver/transmitter located within the MRI room. In a second transmitting step, the data and/or control data (or representations thereof) are transmitted (preferably wirelessly at about 5 GHz) from the inside receiver/transmitter to be received, decoded and presented to a projector, which projects the still image, video image, and/or audio in the MRI machine bore.

According to another aspect of an embodiment of a method according to the present invention, the still image and/or video image are redirected by a mirror and onto the inside surface of the MRI machine bore.

### BRIEF DESCRIPTION OF THE DRAWINGS

FIG. 1 is a schematic view of a system according to the present invention in relation to an MRI room and machine.

FIG. 2 is a cross-sectional view of an MRI machine, including projector assembly within an MRI bore according to the present invention taken along line 2-2 of FIG. 1.

FIG. 3 is a magnified view of the projector assembly of FIG. 2 according to the present invention.

FIG. 4 is a flow chart describing the method of transferring an audio-visual signal from a source to a projector according to the present invention.

FIGS. 5a-5c are block diagram schematics of various embodiments of an in-bore projector assembly according to the present invention.

### DETAILED DESCRIPTION

Although the disclosure hereof enables those skilled in the art to practice the invention, the embodiments described merely exemplify the invention which may be embodied in other ways. While the preferred embodiment has been described, the details may be changed without departing from the invention, which is defined by the claims. It should be noted that like part numbers represent like parts among the various embodiments.

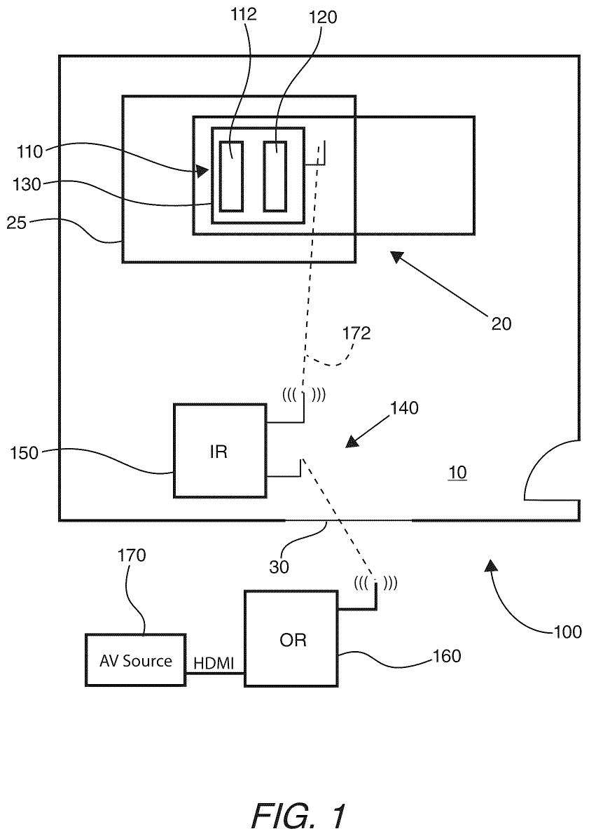

Turning now to the Figures, various embodiments of systems for projecting audio-visual entertainment in MRI rooms may be seen. Beginning with FIG. 1, a first embodiment of a system 100 may be seen in connection with an MRI room 10, MRI machine 20 having an MRI bore 25. An MRI room 10 generally includes at least one type of MRI machine 20 and the room is shielded to prevent radio-frequency (RF) energy from entering the room during the MRI process (and to prevent RF interference). MRI machines are well known in the art and comprise a bore 25 surrounded by a superconducting electromagnetic coil that generates a strong static magnetic field for medical diagnostics. In various embodiments of the system according to the present invention, the system 100 is provided within or proximate the bore 25 of the MRI machine 20.

The system 100 preferably comprises a projector assembly 110 in communication, preferably wireless but wired connections are also contemplated, with a transmission system 140. The projector assembly 110 preferably comprises a projector 112 operatively situated with respect to a reflector or mirror 180. The transmission system 140 preferably comprises an in-room receiver/transmitter 150 (“IR RX/TX”), which is also preferably located within the MRI room 10. The IR RX/TX 150 is in communication, preferably wireless electromagnetic, with an out-of-room receiver/transmitter 160 (“OR RX/TX”), located outside the MRI room 10, which is in further communication (wired or wireless) with an audio-visual data source 170 to relay a graphic, video and/or audio signal (“signal”) 172.

With respect to the projector assembly 110, the projector 112 may be any type of projector including, but not limited to, digital light processing, liquid crystal on silicon, LED, or laser, or other projection technology now known or later developed, so long as a projected video image therefrom may be reflected from a mirror, the first reflection configured for a further (or second) reflection from a display surface (e.g., an interior MRI bore surface). The projector 112 may be an off-the-shelf projector such as a conference room style projector or, preferably, a smaller sized pico-projector, which may be powered by a DC power source. If an off-the-shelf projector is utilized, however, the projector 112 is preferably modified from its standard design to remove all or substantially all magnetic materials, including ferrous (iron), to avoid problems while the MRI machine 20 is in use. For instance, any iron core inductors should be replaced with air core inductors 114. Also, when using an off-the-shelf projector, some electrical operation may be facilitated by a printed circuit board (PCB) 120, both the projector and PCB preferably being mounted within an RF-shielded case 130.

The projector 112 may be supplied with, or modified to include, a high refresh rate. Generally speaking, perceptible video images may be projected at a minimum of 30 frames per second (fps) but is more common to be projected at about 60-75 fps. It has been discovered in the MRI environment that such refresh rate may lead to audible noise due to step currents provided to the light source (e.g., LEDs). Those step currents are understood to create a magnetic field during switching which may cause physical movement or vibration of components that may, in turn, cause such audible noise. Such noise may be undesirable. In an effort to reduce the audibility of such noise, the refresh rate of the projector can be increased so that the frequency of the activation/deactivation of the LED step currents is sufficiently high to reduce perceptibility of such noise. Humans generally are thought to be most audibly sensitive to sounds between 500 Hz and 4,000 Hz, while the normal hearing range is understood to be about 20 Hz to about 20,000 Hz. If the refresh rate of each LED (RGB) is increased to about 2,000 Hz to about 7,000 Hz, or higher, sufficient sound reduction may be achieved.

The projector 112 is preferably in electronic communication with the PCB 120, both to receive power and a communication signal 172 from the PCB 120. Power may be transferred to the projector 112 via conventional electrical wires (e.g., coupled to power mains) or portable power (e.g., lithium polymer or other battery) and the signal 172 may be transferred by a conventional high-definition multimedia interface (HDMI) cord, having been converted from a received wireless communication, as described further below. In use, the projector 112 beams, outward from the case 130, a projection 116 of a still or video image decoded from the signal 172 received from the PCB 120, to be viewed by a patient. The projector 112 may further include a power switch 118, such as a binary switch or button.

Located proximate to the projector 112, the PCB 120 is preferably a custom printed circuit board capable of converting and transferring power from a power source 123 to the projector 112 and capable of receiving a signal 172 from the transmission system 140 and creating a corresponding graphic, video and/or audio output 122 to send to the projector 112 via HDMI cord. The power source 123 may be a battery, such as a rechargeable battery or conventional one-use battery. For example, an embodiment of a custom PCB 120 according to the present invention may comprise a three-tiered (celled) 3S-lithium ion battery. However, these types of batteries usually output around 11V, which would need to be stepped down to 5V in transferring power to the projector 112. Therefore, a two-tiered (celled) 3S-lithium ion battery with a linear regulator 123a (not shown) is preferred. Linear regulators are preferable, as they do not cause electromagnetic interference. The linear regulator 123a may be a conventional linear regulator known in the art. Linear regulators typically dissipate heat, therefore the linear regulator 123a is preferably located proximate to, but outside of, the RF-shielded case 130, so as to protect the other components of the projector assembly 110 from heat exhaust.

In still other embodiments, the power source 123 may be a wall outlet or the MRI machine 20, connected to the PCB 120 through a cord (e.g., a USB cable). For example, the system 100 may be powered through a plug built into an MRI table, which may translate within the MRI machine 20. Such embodiments may forego the inclusion of a battery, since there is a constant power source supplying power to the system 100. Other embodiments may include both a battery and cable and it is up to the medical professional to decide which to use to provide power to the system 100.

The PCB 120 further preferably comprises a 5 GHz radio transceiver or receiver 124, a memory component 125 (not shown), and possibly a storage component 126 (not shown). The radio 124 may be one known in the art capable of wirelessly receiving communications from the transmission system 140. When a signal 172 is received from the transmission system 140, the receiver may transfer for temporary storage the input 121 in the memory component 125 (e.g. dedicated RAM or solid state drive) while the input 121 is being converted to HDMI and transmitted to the projector 112 as the output 122. The memory component 125 may further, or alternatively, comprise non-volatile memory (e.g. flash or ROM), which stores programmable (preferably re-programmable) and/or executable software or firmware to help the function of the PCB 120 in receiving input 121, decoding it, and transmitting to the projector 112.

The PCB 120 may further comprise or be removably couplable to/from a long term storage component 126 (e.g. flash drive, hard drive, solid state drive (SSD), etc.) (not shown), which may store previously recorded or received transmissions to be accessed for projection at a later time. If the storage component 126 is located within an MRI room, it is preferred that it not include moving parts (e.g., as in a hard drive), so such storage should be kept outside the room and accessed via a wired or wireless connection. For example, should there be any problem requiring maintenance in the transmission assembly 140 which would otherwise prevent the signal 172 from reaching the projection assembly 110, the long term storage component 126 may instead provide the signal 172. If included, such long-term storage component 126 is preferably located within the RF-shielded case 130 as well, for the same reasons as the other parts mentioned above.

Finally, in some cases, the PCB 120 may also further comprise a boost converter 127 between the power source 123 and the receiver 124. Boost converters are well known in the art to step up voltage. In cases where the voltage of the power source 123 may not be suitable for the receiver 124, the boost converter 127 may boost the available DC voltage to meet the needs of the receiver 124. The boost converter 127 is preferably able to boost the voltage to between 3.7V and 5V.

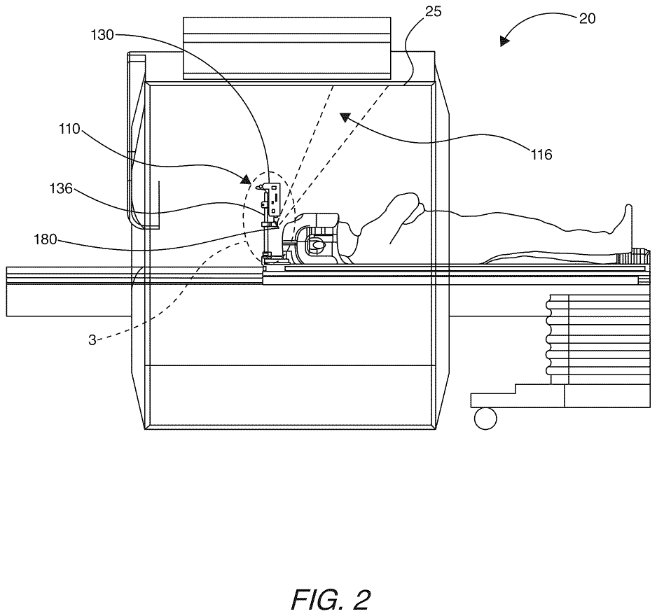

The projector 112 and the PCB 120 are preferably stored within an RF-shielded (i.e. shielded from electromagnetic radiation coming in and out) case 130 which may be mounted within the MRI bore 25, as seen in FIG. 2. Though a patient is shown in a head-first position, it is to be understood that the relative positioning of the projector 112 with respect to a patient's head (or otherwise) may be maintained if a patient position were to be reversed (feet first). The case 130 is preferably an RF-shielded case known in the art, such as a faraday cage case. The case 130 may be any shape which may accommodate the projector 112 and PCB 120 and preferably includes one aperture 132 through which the projection 116 may be beamed. However, since an object of the case 130 is to prevent electromagnetic radiation generated by the projector assembly 110 electronics from interfering with the MRI scan, the aperture 132 presents a challenge, as the electromagnetic radiation may seep through the aperture 132. Four different embodiments of RF shielding the aperture 132 have been developed to deal with this problem.

Firstly, positional radiation reduction may be attempted, alone or in combination with any of the additional RF shielding techniques described herein. In the positional technique, the aperture 132 is simply cut into the case 130 with no radiation filter and the projector assembly 110 is positioned in or near the MRI bore 25 to limit the chance of electromagnetic radiation from the projector assembly 110 from interfering with the MRI scan. This embodiment is cost effective as it requires no extra components or assembly, but risks interference with the MRI scan if electromagnetic radiation were to leak out of the case 130. However, if the projection assembly 110 and/or aperture 132 is placed in an accurate location to limit errant electromagnetic radiation (such as approximately in a central location of a cross section of the bore 25), it may be a preferable solution.

A second type of embodiment of the aperture 132 pairs with a waveguide 132b to reduce or substantially eliminate electromagnetic radiation seepage out of the case 130. The waveguide 132b may be a conventional waveguide well known in the art (e.g., a rectangular, circular, or elliptical waveguide). Preferably, the waveguide 132b is oriented to reduce or completely prevent electromagnetic seepage through the aperture 132 and out of the projection assembly 110. The advantages of this embodiment are that waveguides are well known and understood in the art and easy to customize in manufacturing. However, the disadvantages of this solution are that waveguides (that are sized to reduce image distortion) may be dimensionally unfeasible and expensive, especially when customized.

The third and fourth types of embodiments of the aperture 132 both involve a form of mesh filtration for the ambient electromagnetic radiation. The third embodiment features directional mesh 132c installed in the aperture 132, wherein woven strands of electromagnetic materials are manufactured in such a way as to inhibit propagation of the electromagnetic radiation. Directional mesh is known in the art to inhibit and reduce radiation by creating crossing patterns of conductive material which attenuate the radiation. The advantages of the third embodiment are that directional mesh is relatively cheap (as compared to a waveguide), while still being an effective electromagnetic radiation filter. The disadvantages of directional mesh are that it may also inhibit the projection 116 quality by causing moiré effects and other types of distortion to the projection 116. However, refinement of the projector 112 settings and optics may be able to account for some corrections of these distortion effects.

A fourth type of embodiment of the aperture 132 according to the present invention comprises a filter of random mesh 132d. Similar to the directional mesh 132c, random mesh 132d is known in the art to filter and inhibit electromagnetic radiation through interconnected conductive strands of material. However, unlike directional mesh that typically features a grid-like layout of material strands, random mesh exhibits a more chaotic and unpredictable (i.e., at least substantially random) arrangement of strands (similar to a non-woven fabric), such that holes through the mesh are less consistent in size and may be non-existent in areas. The advantages of random mesh embodiments are the same as directional mesh, while the disadvantages are more limited in that random mesh does not tend to distort the projection 116 quite as much as the directional mesh. Directional and random mesh are known in the art and typically commercially available, though they may be modified to fit the aperture 132 and/or according to the type of projector 112 in use in the current invention.

Other forms of RF filtration devices are contemplated as well. For instance, some embodiments of the system 100 according to the present invention may use RF-filtering glass and/or film in addition to, or alternatively to, the waveguide, directional mesh and/or random mesh 132b-d. RF glass and RF film are both well known in the art to filter and/or shield technology from RF radiation.

The case 130 also preferably comprises at least one antenna 137 affixed to the outside surface. The antenna 137 facilitates the communication between the projection assembly 110 and the transmission assembly 140. While shown as a longitudinal, external antenna, such as an omni-directional WiFi antenna with an SMA interface, for example, a chip antenna could alternatively be used.

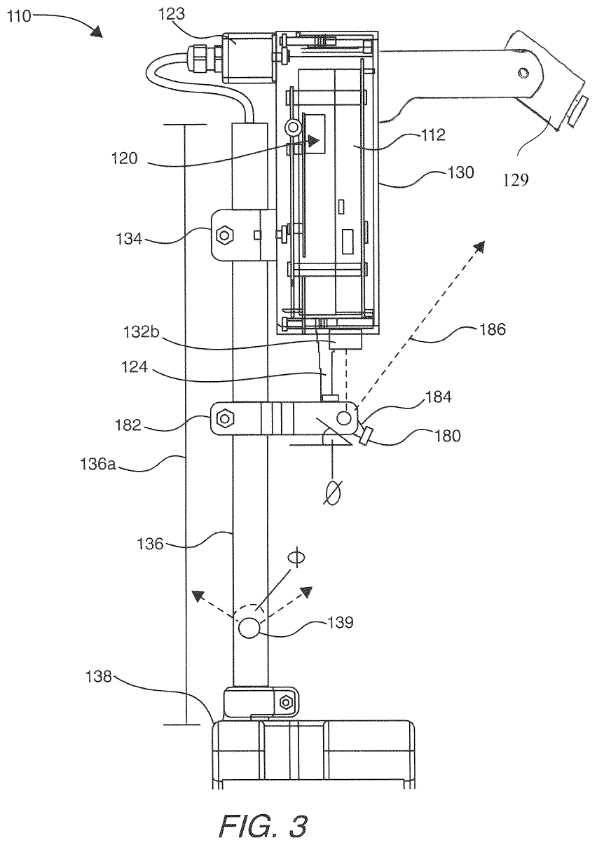

As seen in more detail in FIG. 3, the RF-shielded case 130 may also be removably attached to a case mount 134. Preferably, the case 130 may be fastened to the case mount 134 using conventional removable fasteners (e.g., screws) or adhered thereto or formed integrally therewith. The case mount 134 is preferably further attached to a stand 136. The stand 136 preferably includes a rod (e.g., having a circular or other geometric cross-section) or rail comprising a stand height 136a sufficient to raise the case mount 134 (and consequently the case 130) to meet the specific requirements of the situation, depending on the height of the MRI machine 20 and/or bore 25. The case mount 134 is preferably adjustable (such as by friction clamp), such that the position of the case 130 may be variable along the stand height 136a. In most embodiments, the stand 136 preferably comprises a mating mechanism 138 at one end, which may removably attach, couple, and/or stabilize the stand 136 relative to the MRI machine 20 and/or another object (e.g., a patient table) attached to or located proximate the MRI machine 20 or within the bore 25 to keep the stand 136 upright. Most older MRI machines have attached, fixed tables on which the stand 136 may be stabilized. Newer MRI machines may include removable tables. Either way, the stand 136 is preferably adaptable to be removably attached, coupled, and/or stabilized to the fixed or removable table of the MRI machine 20, depending on the machine model. Additionally or alternatively, the stand 136 may be constructed to mate with and/or operatively cooperate with a variety of MRI manufacturer tables or a specific MRI manufacturer table. Indeed, the stand 136 may be suspended above the table (along a table midline), such as by bridging the table with a support that is secured or coupled to longitudinal table edges.

In some embodiments, the stand 136 further comprises a pivot 139 located along the stand height 136a, allowing a portion of the stand 136 (and consequently the case 130) to rotate an angle Φ, preferably bidirectionally, up to 90 degrees (relative to a vertical position) to further account for the needs of the specific situation to help the patient view the projection 116 optimally, such as when a patient is positioned in the bore 25 on his or her lateral side. The pivot 139 may be located anywhere along the stand height 136a, but is preferably located at or near the stand extremities to allow a large portion of the stand 136 (with the case 130 and mirror 180, further described below) to pivot relative to its upright position. Other embodiments of the stand 136 according to the present invention may comprise more than one pivot 139, located at various points along the stand height 136a. The stand 136 and case mount 134 are preferably formed from non-magnetic, and more preferably non-metallic components, such as molded or printed plastic, so long as the components are sufficient to support the projector 112, mirror 180, and attempt to minimize or eliminate any proton signal or imaging interference.

In some embodiments of the present invention, the projection assembly 110 further comprises a microphone 128 and/or camera 129 in electronic communication with the PCB 120 and configured to transmit signals back out of the MRI room 10. During the MRI procedure, it may be advantageous for the medical professional to have instantaneous communication with a patient, such as a patient wishing for higher volume for their entertainment. The signals from the microphone 128 and/or camera 129 would be transferred (wirelessly or wired) through the transmission system 140 to be received by the medical professional, who may respond to the needs of the patient.

In use, the projection assembly 110 may be packaged and sold in kits. In some embodiments, each kit includes individual parts that may be combined to form an entire projection assembly 110. In other embodiments, each kit includes a projection assembly 110 fully formed. In further embodiments, kits may include a plurality of projection assemblies 110. In some instances, medical professionals may wish to switch projection assemblies between patients. Switching between two projection assemblies 110 may help to ensure a full battery life in use, since the unused assembly 110 may interface a battery charger, and may help sterilization, as the non-used assembly 110 may also be sterilized in between patients. Additionally or alternatively, a single projection assembly 110 may be provided in a kit with multiple interchangeable batteries, which may be charged when not in use. Each kit may further include a plug-in charger and/or wireless charger for the projection assembly(s) 110. The wireless charger may comply, for instance, with the QI standard for wireless charging.

Turning now to the transmission system 140, the transmission system 140 according to various embodiments of the present invention comprises the IR TX/RX 150, the OR TX/RX 160, and the audio-visual source 170. As can be seen with reference back to FIG. 1, the transmission system 140 is configured to relay data encoded with still and/or video image, and/or audio data from the source 170 to the OR TX/RX 160, then from the OR TX/RX 160 to the IR TX/RX 150, then from the IR TX/RX 150 to the projection assembly 110, where it may be projected onto a portion of the bore 25 and viewed by the patient during the procedure (the portion being preferably at least substantially radially aligned with the patient's line of sight when the patient's head is positioned in neutral spine, thereby requiring minimal elevation, depression, abduction, or adduction of the eyes). In the past, transmitting any kind of signal into an MRI room has been problematic due to the RF-shielding of the room that keeps the electromagnetic radiation from escaping during a procedure. Applicants believe that the system 100 solves this problem through the transmission system 140, preferably through communication up-conversion and down-conversion.

Much like the projection assembly case 130, the IR RX/TX 150 (and perhaps the OR RX/TX 160) is preferably substantially RF-shielded to prevent electromagnetic radiation seepage out of the IR RX/TX 150 to prevent interference with the MRI procedure. Both the IR RX/TX 150 and OR RX/TX 160 further preferably comprise a radio transceiver (or receiver 152 and/or transmitter 154), allowing them to pass video data along the path from the source 170 to the projection assembly 110. Specifically, the source 170 transmits the signal 172, either wirelessly or via cord (e.g., HDMI cord) to the OR RX/TX 160. Both the source 170 and the OR RX/TX 160 are preferably located outside of the shielded MRI room 10, with the OR RX/TX 160 preferably being located at least proximate to the RF-shielded MRI room window 30, although the OR RX/TX 160 is preferably capable of transmitting through an MRI room wall (e.g., with a wired connection) as well. The IR TX/RX 150 is also located proximate the window 30, however the IR TX/RX 150 is located within the MRI room 10. In some embodiments of the present invention, the IR RX/TX 150 and/or OR RX/TX 160 may include a waveguide as well, with the same function as the waveguide 132b of the projection assembly 110.

In some embodiments of the present invention, the OR RX/TX 160 preferably only comprises the RF-shielding and a transmitter 154, especially in cases where the OR RX/TX 160 is connected to the source 170 via wire and has no need for a wireless receiver. This embodiment may save space and cost in manufacturing the OR RX/TX 160. In other embodiments, such as those explained above, the OR RX/TX 160 preferably comprises the RF-shielding, transmitter 154, and receiver 152. The receiver 152 is advantageous for embodiments of the present invention in which the projection assembly 110 comprises a microphone 128 and/or camera 129. In such embodiments, the signals of the microphone 128 and/or camera 129 may be transmitted in reverse of the source signal 172, going from the projection assembly 110 to the IR RX/TX 150 then to the OR RX/TX 160. Such an assembly would allow a line of communication between medical professionals and patients mid-procedure.

As stated above, a problem with communicating signals into an MRI room is that an MRI room is or should be radiation shielded, making it difficult for standard or common communication signals to get out of or into it. To solve this problem, The OR RX/TX 160 according to various embodiments of the present application wirelessly transmits the signal 172, preferably at 60 GHz, a rate much higher than most signal transmissions. This rate allows the signal 172 to reliably penetrate through any RF mesh that may be provided on or embedded in the window 30. However, the signal is also a line-of-sight signal, meaning that the signal 172 will not be able to go around solid objects in its way when sent at 60 GHz. Therefore, the IR RX/TX 150 is used as a communication intermediary to step the rate down to 5 GHz, allowing it to travel around solid objects. The IR RX/TX 150 is preferably capable of receiving the 60 GHz signal 172 from the OR RX/TX 160, then steps the signal 172 down to 5 GHz before passing it onto the projection assembly 110. The 5 GHz signal 172 may then traverse the solid objects in the MRI room 10 to reach the projection assembly 110.

The communication signal 172 originates in a first format (e.g., HDMI) from the audio-visual source 170, located outside of the MRI room 10. This audio-visual source 170 may be any entertainment graphic, video and/or audio signal generator known in the art (e.g., television, DVD player, smartphone, etc.), including signals streamed over the internet from an audio-visual content provider. The audio-visual source 170 preferably outputs the signal 172 via cord (e.g., HDMI cord) to preserve the quality as much as possible before transmission into the MRI room 10, but may also transmit the signal 172 to the OR RX/TX 160 wirelessly (e.g., Bluetooth® or wifi) in some embodiments.

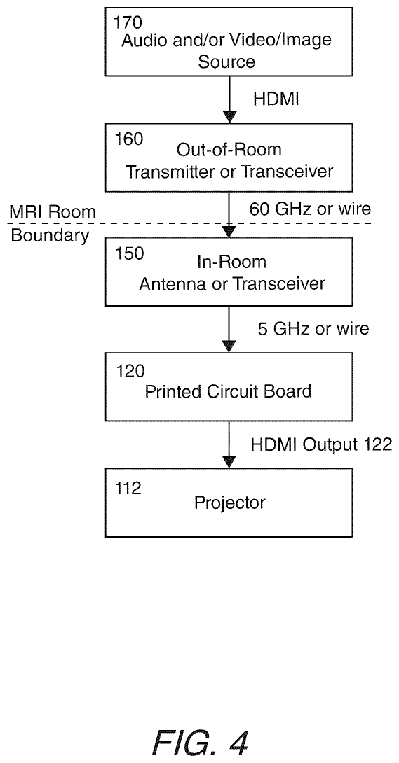

In use, a patient may be asked to pick from various types of entertainment that may be sent by the signal source 170 during a procedure, or a care provider or other person may select the images/audio to be experienced by the patient. The path of the communication signal 172 from the source 170 to the projector 112 is seen in the flowchart of FIG. 4. Once a source 170 is selected, it is preferably connected via HDMI cord to the OR RX/TX 160, which then converts the communication to a wireless signal (preferably about 60 GHz) to transmit data to the IR RX/TX 150, which preferably down-converts the communication (preferably to about 5 GHz) to pass data along to the PCB 120 of the projector assembly 110. There, the encoded data may be temporarily stored in the memory component 125 before being decoded and re-encoded to be transmitted again via HDMI cord to the projector 112, which projects an image and may output an audio signal based on the data received from the PCB. In some embodiments, the projection 116 may be aimed directly onto the ceiling of the bore 25 by selectively adjusting the projector assembly 110 along the stand height 136a and particularly aiming the projection 116. In other embodiments however, such as those where the projector assembly 110 may not be able to aim directly at the ceiling of the bore 25 for whatever reason (e.g., the projection assembly 110 is located within the bore 25), the projector assembly 110 further preferably comprises the mirror 180 used to reflect the projection 116 into place on the ceiling of the MRI bore 25.

Similar to the case 130, the mirror 180 is preferably removably attached to the stand 136 via a mount 182, allowing the position of the mirror 180 to be adjustable along the stand height 136a to acquire the optimum projection 116 shape and size. To reflect the projection 116 onto a desired portion of the bore 25, the mirror 180 is preferably at an angle Ø relative to a line perpendicular to the stand 136, as seen in FIG. 3. This angle Ø may be between 0° and 90°, depending on the position of the projection assembly 110, mirror 180, and/or system 100 relative to the bore 25, and may be adjustable by rotating the mirror 180 to find the optimum angle Ø for the projection 116.

In some embodiments, the mirror 180 may be rectangular and flat, and in a most preferred embodiment is a first-surface (or front-surface) mirror. In other embodiments, shapes such as circular or oval may be preferred and/or the mirror 180 may have an alternative topology, such as having a one or more concave portions (e.g., along an edge 184), such as to preempt image distortions caused by eventual display on a surface that is laterally curved with respect to a video image projection direction 186.

For example, most MRI bores are circular in cross-section (taken perpendicular to view of FIG. 2) to allow a patient to remain in a supine or lateral decubitus position within the bore while the MRI scan procedure is taking place. Thus, the inside ceiling of the bore is usually curved. In embodiments of the system 100 according to the present invention, this can present a problem, where a flat projection 116 is thrown onto a curved surface. This problem may cause the projection 116 on the bore 25 ceiling to be stretched and/or distorted, especially noticeable on a bottom portion of the image, furthest from the projector 112. To compensate, the optics or software of the projector 112 may be set such that the projection 116 appear to be a consistent size and shape (e.g., rectangular) even when projected onto the bore 25 ceiling.

In some embodiments, in addition or alternative to presetting the projector 112 to account for distortion, it may be necessary to pre-distort the signal 172, such that the projection 116 ends up looking undistorted on the bore wall. Such pre-distortion of the signal 172 may take place at any point along the signal pathway (i.e. at the signal source 170, at either RX/TX 160 or 150, or at the projection assembly 110 before the signal 172 is projected). For instance, a field-programmable gate array (FPGA) or application-specific integrated circuit (ASIC) may be used to pre-distort the signal 172 to correct for the curvature of the bore. In such cases, the system 100 may even be able to sense the angle Ø of the mirror and correct distortion automatically as the desired location of the projection 116 is adjusted by an operator. Such pre-distortion solutions may be paired with embodiments of a flat, rectangular mirror 180 to achieve the desired projection 116.

In addition, or alternatively, the mirror 180 may be curved (i.e. convex or concave), as seen in FIG. 3. This curvature is preferably configured to bend the projection 116 to account for the curved surface of the bore 25, such that the projection 116 appears to the patient as a relatively flat image of appropriate proportions. Further, with a curved mirror 180 and/or lens of the projector 112, it may be possible to collimate the light rays of the projection 116. In such instances, the system 100 may further comprise a combiner 188 on the surface of the bore 25, wherein the projection 116 is reflected off the combiner 188, creating a heads-up display (HUD) and/or augmented-reality (AR) effect. The collimated light reflected off the combiner 188 would appear to the patient to be further in distance from their eyes than it is in reality, creating the illusion that the bore 25 does not exist and they are watching a screen set away from their face. This effect may further alleviate stress and anxiety associated with being within the bore 25 during the MRI procedure.

Curved mirror 180 solutions may also be paired with pre-distortion solutions mentioned above and fine-tuned to achieve optimal projection quality. However, a curved mirror 180 may affect the focus of the image in the projection 116, making the image appear hazy (out-of-focus). To correct this problem, in conjunction with or alternatively to pre-distortion solutions mentioned above, some embodiments of the present invention may employ a plurality of mirrors 180 (and/or one or more optical lenses) to fine-tune the projection 116 and achieve optimum quality.

In some alternative embodiments of the system 100 according to the present invention, various wireless connections of the system 100 may be replaced by wired connections through a wireway 190 (not pictured) to reduce the chance of signal loss or other problems with the signal 172. For instance, various embodiments of the system 100 according to the present invention may replace the transmission assembly 140 with a wireway 190. This wireway 190 would connect the signal source 170 all the way to the projector assembly 110, possibly carrying both the signal 172 and acting as the power source 123 to the projector assembly 110. To accomplish this wired connection, the MRI room 10 preferably comprises a penetration panel 40 installed into the RF-shielded MRI room 10. The penetration panel 40 also preferably comprises an RF filter 45, preventing RF-energy from entering during the MRI procedure. The wireway 190 threads through the penetration panel 40, and more specifically through the RF filter 45, to enter the MRI room 10, where it eventually connects mechanically and electronically with the projector assembly 110.

Alternatively, in some embodiments of the system 100 according to the present invention, the transmission assembly 140 remains, but is connected via wired connections through wireway 190. For instance, the signal source 170 may be connected to the OR RX/TX 160 as described above. However, the OR RX/TX 160 and IR RX/TX 150 may then be connected via wireway 190 instead of wirelessly. In such an embodiment, the MRI room 10 and/or window 30 preferably comprises a penetration panel 40 and RF filter 45, as discussed above, to allow wireway 190 to be threaded into the MRI room 10 without releasing RF energy. The IR RX/TX 150 still includes a wireless transmitter 154 to transmit the signal across the MRI room 10. Thus, the 5G signal 172 may pass by wireway 190 from the signal source 170, through the OR RX/TX 160, to the IR RX/TX 150, then wirelessly across the room 10 to the projector assembly 110 to be displayed within the bore 25.

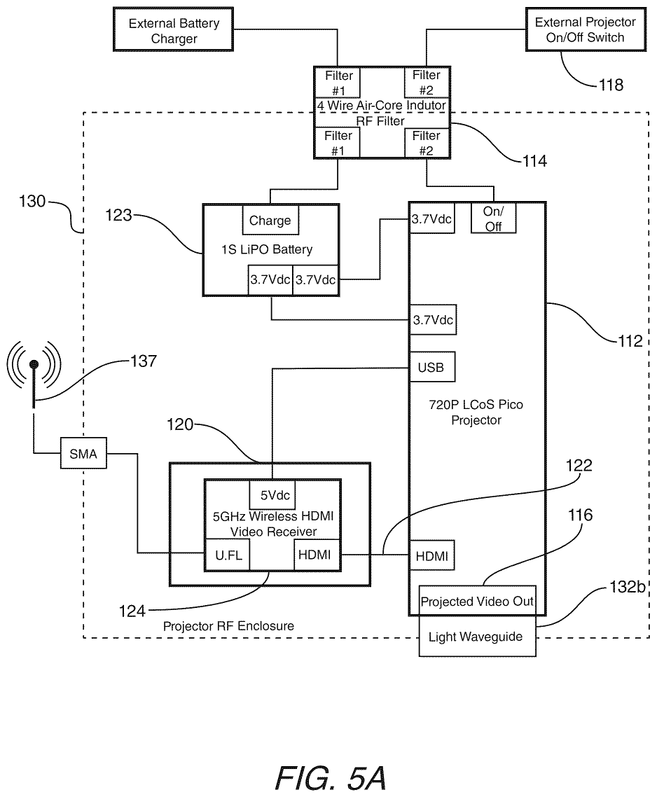

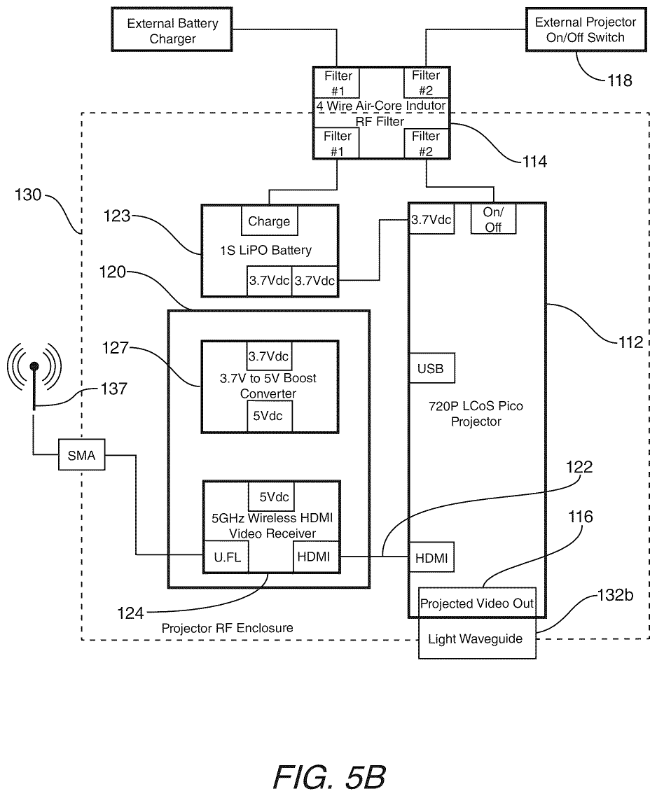

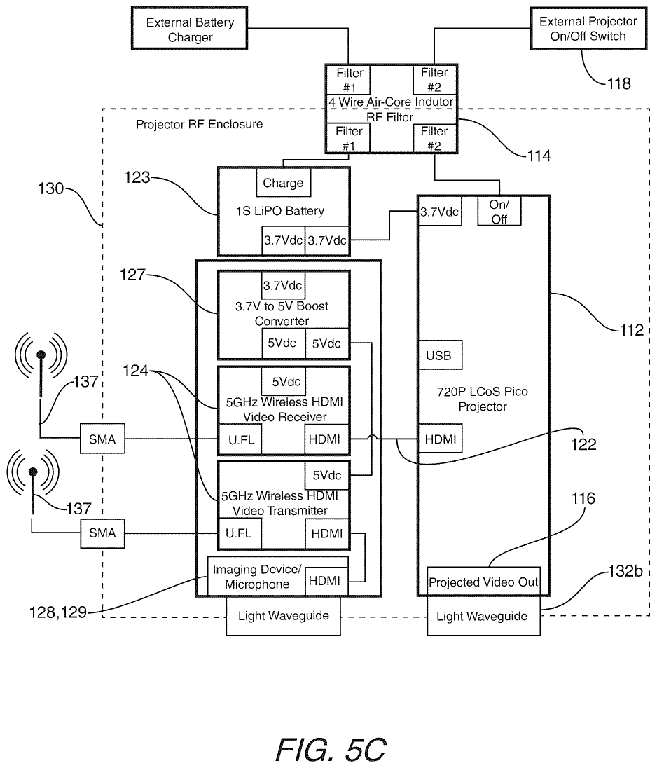

FIGS. 5a-5c show schematic views of three different possible embodiments of a connected projector 110 and PCB 120 within the RF-shielded case 130 according to the present invention. FIG. 5a depicts a basic connection, wherein the PCB 120 comprises basically only a receiver 124 and connected power source 123 and antenna 137. FIG. 5b's connection is only slightly more complicated, wherein the PCB 120 further comprises the boost converter 127.

FIG. 5c depicts an even more complicated connection, wherein the PCB 120 comprises a radio transceiver 124, boost converter 127, microphone 128 and camera 129, and connected power source 123 and plurality of antennas 137.

The foregoing is illustrative only of the principles of embodiments according to the present invention. Modifications and changes will readily occur to those skilled in the art, so it is not desired to limit the invention to the exact disclosure herein provided. While the preferred embodiment has been described, the details may be changed without departing from the invention.

We claim:

1. A system for projecting an image within an MRI bore comprising:
a projector;
a mirror;
a first receiver/transmitter in communication with the projector;
a second receiver/transmitter in communication with the first receiver/transmitter; and
an audio-visual data source in communication with the second receiver/transmitter,
wherein the audio-visual data source produces a signal,
wherein the signal is communicated from the audio-visual data source to the second receiver/transmitter, from the second receiver/transmitter to the first receiver/transmitter, and from the first receiver/transmitter to the projector,
wherein the projector projects a still or video image decoded from the signal, and
wherein the projection is reflected off of the mirror and onto the inside of an MRI machine bore.

2. The projection system of claim 1, wherein the projector and mirror are located within the MRI bore.

3. The projection system of claim 2, wherein the first receiver/transmitter is located inside of an MRI room and the second receiver/transmitter and audio-visual data source are located outside of the MRI room.

4. The projection system of claim 3, further comprising:
a printed circuit board (PCB), which receives the signal from the first receiver/transmitter, decodes the signal into a signal output, and transmits the signal output to the projector through wire; and
an RF-shielded case comprising an aperture through which the projection is beamed,
wherein both the projector and PCB are located within the RF-shielded case.

5. The projection system of claim 4, wherein the PCB comprises a power source and the PCB converts and transfers power from the power source to the projector.

6. The projection system of claim 5, wherein the power source is a battery.

7. The projection system of claim 5, wherein the power source is a wall outlet.

8. The projection system of claim 5, wherein the power source is the MRI machine.

9. The projection system of claim 4, wherein the PCB further comprises a radio receiver, a memory component, and a storage component, wherein the memory component temporarily stores the signal while it is being converted to the signal output.

10. The projection assembly of claim 9, wherein the memory component further comprises non-volatile memory.

11. The projection assembly of claim 10, wherein the PCB further comprises a boost converter.

12. The projection system of claim 5, wherein the RF-shielded case further comprises an electromagnetic radiation limiting device disposed about the aperture.

13. The projection system of claim 12, wherein the electromagnetic radiation limiting device comprises a waveguide.

14. The projection system of claim 12, wherein the electromagnetic radiation limiting device comprises directional mesh.

15. The projection system of claim 12, wherein the electromagnetic radiation limiting device comprises random mesh.

16. A method for projecting an image and/or video into an MRI bore comprising the steps of:
generating an image, audio, and/or video signal from an audio-visual source;
in a first transmitting step, transmitting the signal from the audio-visual source to an outside receiver/transmitter located outside an MRI room;
in a second transmitting step, transmitting the signal from the outside receiver/transmitter to an inside receiver/transmitter located within the MRI room;
in a third transmitting step, transmitting the signal from the inside receiver/transmitter to a projector;
decoding the signal into a projectable output; and
projecting the projectable output onto the inside surface of an MRI machine bore.

17. The method of claim 16, wherein the second transmitting step is accomplished wirelessly.

18. The method of claim 17, further comprising the step of converting the signal to a wireless signal of approximately 60 GHz between the first and second transmitting steps.

19. The method of claim 18, further comprising the step of stepping down the signal from approximately 60 GHz to approximately 5 GHz between the second and third transmitting steps.

20. The method of claim 19, the projection step further comprising the step of reflecting the projectable output off a mirror and onto the inside surface of the MRI machine bore.
